(19) United States
(12) Patent Application Publication
(10) Pub. No.: US 2026/0362658 A1
(43) Pub. Date: Nov. 12, 2026

(54) POWER SUPPLY DEVICE AND POWER SUPPLY SYSTEM

(71) Applicant: CHICONY POWER TECHNOLOGY CO., LTD., NEW TAIPEI CITY (TW)

(72) Inventors: Yung Hung HSIAO, NEW TAIPEI CITY (TW); Hao Chieh CHANG, NEW TAIPEI CITY (TW); Han Liang HUANG, NEW TAIPEI CITY (TW); Chun Hsiung YEH, NEW TAIPEI CITY (TW); Yu Xian ZENG, NEW TAIPEI CITY (TW)

(21) Appl. No.: 19/225,220

(22) Filed: Jun. 2, 2025

(30) Foreign Application Priority Data
May 8, 2025 (TW) 114117388

(51) Int. Cl. H05K 7/20; H05K 1/02

(52) U.S. Cl. CPC H05K 7/20927; H05K 1/0203; H05K 7/20436; H05K 7/209

(57) ABSTRACT

A power supply device includes a liquid cooling rack, a circuit module, and an insulating thermal pad. The liquid cooling rack includes a first liquid cooling plate and a second liquid cooling plate. The circuit module includes a circuit board, a first component, a second component, and third components. The circuit board is disposed between the first and second liquid cooling plates. The first and second components are disposed on a surface of the circuit board and have different heights. The third components are disposed on the other surface of the circuit board and have substantially the same height. Heat generated by the third components is conducted to the first liquid cooling plate. The insulating thermal pad is disposed between the circuit module and the second liquid cooling plate. Heat generated by the first and second components is conducted to the second liquid cooling plate through the insulating thermal pad.

### BACKGROUND OF THE PRESENT DISCLOSURE

### Field of the Present Disclosure

The present disclosure relates to a power supply device and a power supply system, and particularly to a liquid cooling power supply device and a liquid cooling power supply system for a rackmount server.

### Description of the Prior Art

As computing performance of AI servers increases, requirements for output powers, power densities, and operating temperatures of power supplies of AI servers are becoming higher and higher. Current power supplies mainly use fans for heat dissipation. However, a thermal design power (TDP) of a fan-cooling CPU or GPU of a conventional size is physically limited by thermodynamics. If power consumption of the CPU or GPU exceeds 700 W, increasing a fan speed or enlarging a heat sink will not effectively remove heat from electronic components. The accumulated heat will damage the electronic components in the power supply, thereby reducing stability and a service life of the power supply. In view of the above, the industry has begun to introduce liquid cooling technology to improve heat dissipation efficiency. However, heat dissipation efficiency of current liquid cooling power supplies cannot meet the industry's demand for high heat dissipation efficiency, and still needs to be improved.

### SUMMARY OF THE PRESENT DISCLOSURE

In order to solve the aforementioned technical problem, the present disclosure provides a power supply device, which includes a liquid cooling rack, a first circuit module, and an insulating thermal pad. The liquid cooling rack includes a first liquid cooling plate and a second liquid cooling plate located above the first liquid cooling plate. The first circuit module includes a first circuit board, a first component, a second component, and a plurality of third components. The first circuit board is disposed on the first liquid cooling plate. The first component and the second component are disposed on a surface of the first circuit board close to the second liquid cooling plate. A height of the first component is greater than a height of the second component. Heights of the third components are substantially the same. The third components are disposed on a surface of the first circuit board close to the first liquid cooling plate. Heat generated by the third components is directly or indirectly conducted to the first liquid cooling plate. The insulating thermal pad is disposed between the first circuit module and the second liquid cooling plate. Heat generated by the first component and the second component is conducted to the second liquid cooling plate through the insulating thermal pad.

The present disclosure further provides a power supply device, which includes a liquid cooling rack, a first circuit module, a second circuit module, a third circuit module, and a metal heat sink. The liquid cooling rack includes a first liquid cooling plate, a second liquid cooling plate, and a third liquid cooling plate sequentially from bottom to top. The first circuit module includes a first circuit board, a first component, a second component, and a plurality of third components. The first circuit board is disposed on the first liquid cooling plate. The first component and the second component are disposed on a surface of the first circuit board close to the second liquid cooling plate. A height of the first component is greater than a height of the second component. The second liquid cooling plate is provided with a protrusion. The protrusion directly or indirectly contacts the second component. Heights of the third components are substantially the same. The third components are disposed on a surface of the first circuit board close to the first liquid cooling plate, and directly or indirectly contact the first liquid cooling plate. The second circuit module includes a second circuit board and a plurality of fourth components. The second circuit board is adjacent to a side of the first liquid cooling plate and is located below the second liquid cooling plate. The fourth components are disposed on a surface of the second circuit board close to the second liquid cooling plate. Heights of the fourth components are substantially the same and are greater than the height of the first component. The second liquid cooling plate includes a first plate corresponding to the first circuit module and a second plate corresponding to the second circuit module. A thickness of the second plate is less than a thickness of the first plate, so that the first component directly or indirectly contacts the first plate, and the fourth components directly or indirectly contact the second plate. The third circuit module includes a third circuit board, a fifth component, a sixth component, and a plurality of seventh components. The third circuit board is disposed between the second liquid cooling plate and the third liquid cooling plate. The fifth component and the sixth component are disposed on a surface of the third circuit board close to the second liquid cooling plate. A height of the fifth component is greater than a height of the sixth component. Heights of the seventh components are substantially the same. The seventh components are disposed on a surface of the third circuit board close to the third liquid cooling plate, and directly or indirectly contact the third liquid cooling plate. The metal heat sink is disposed between the third circuit module and the second liquid cooling plate, and includes a first portion corresponding to the fifth component and a second portion corresponding to the sixth component. A thickness of the second portion is greater than a thickness of the first portion, so that heat generated by the fifth component is conducted to the second liquid cooling plate through the first portion, and heat generated by the sixth component is conducted to the second liquid cooling plate through the second portion.

The present disclosure further provides a power supply system, which includes a plurality of the aforementioned power supply devices and a manifold seat. The power supply devices are arranged side-by-side in a direction parallel to the first side of the first liquid cooling plate. The manifold seat is detachably connected to an inlet port and an outlet port of a manifold of each of the power supply devices, and has an input port and an output port. The input port is connected to the inlet port of each of the power supply devices. The output port is connected to the outlet port of each of the power supply devices.

### BRIEF DESCRIPTION OF THE DRAWINGS

FIG. 1 is a schematic diagram of a power supply device according to a first embodiment of the present disclosure.

FIG. 2 is a schematic diagram of a power supply device according to a second embodiment of the present disclosure.

FIG. 3 is a schematic diagram of a power supply device according to a third embodiment of the present disclosure.

FIG. 4 is a schematic diagram of a power supply device according to a fourth embodiment of the present disclosure.

FIG. 5 is a schematic diagram of a power supply device according to a fifth embodiment of the present disclosure.

FIG. 6 is an exploded view of a liquid cooling rack according to an embodiment of the present disclosure.

FIG. 7 is a schematic diagram of a power supply device according to a sixth embodiment of the present disclosure.

FIG. 8 is an exploded view of the liquid cooling rack in FIG. 7.

FIG. 9 is a schematic diagram of a power supply system and a liquid cooling distribution unit according to an embodiment of the present disclosure.

FIG. 10 is a partial enlarged schematic diagram of a power supply system according to an embodiment of the present disclosure.

### DETAILED DESCRIPTION OF THE EMBODIMENTS

The embodiments of the present invention will be fully described below in conjunction with the accompanying drawings. The elements in the accompanying drawings are not drawn to scale and are merely used to clearly illustrate the embodiments of the present invention. The terms such as “on/above”, “under/below”, “inside”, and “outside” in the present disclosure indicate the positional relationships between the elements based on the positional relationships between the elements shown in the accompanying drawings, and are only for convenience of describing the embodiments of the present invention, and are not intended to limit the present invention. The terms such as “first” and “second” in the present disclosure do not represent any order, quantity, or importance, but are only used to distinguish different elements, parts, and regions.

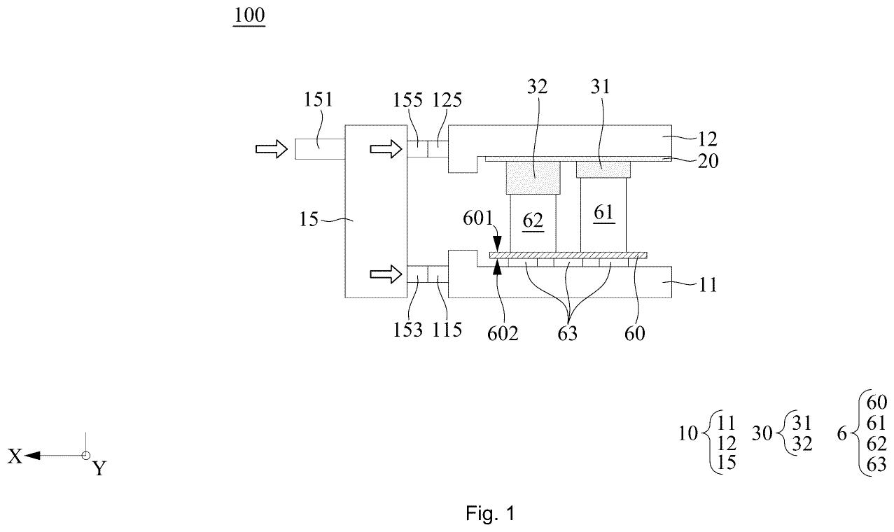

Please refer to FIG. 1, which is a schematic diagram of a power supply device 100 according to a first embodiment of the present disclosure. In the first embodiment, the power supply device 100 includes a liquid cooling rack 10, at least one first circuit module 6, and an insulating thermal pad 20. The liquid cooling rack 10 includes a first liquid cooling plate 11 and a second liquid cooling plate 12 located above the first liquid cooling plate 11. The first circuit module 6 includes a first circuit board 60, at least one first component 61, at least one second component 62, and a plurality of third components 63. The first circuit board 60 is disposed on the first liquid cooling plate 11. The first component 61 and the second component 62 are disposed on a surface 601 of the first circuit board 60 close to the second liquid cooling plate 12, and a height of the first component 61 is greater than a height of the second component 62. Heights of the third components 63 are substantially the same, and the third components 63 are disposed on a surface 602 of the first circuit board 60 close to the first liquid cooling plate 11. Heat generated by the third components 63 is directly or indirectly conducted to the first liquid cooling plate 11. The insulating thermal pad 20 is disposed between the first circuit module 6 and the second liquid cooling plate 12, and heat generated by the first component 61 and the second component 62 is conducted to the second liquid cooling plate 12 through the insulating thermal pad 20.

FIG. 1 illustrates that the insulating thermal pad 20 is a continuous plane covering an entirety of the first circuit module 6. In other embodiments, the insulating thermal pad 20 may include two independent thermal pads covering the first component 61 and the second component 62 respectively. FIG. 1 illustrates that the third components 63 directly contact the first liquid cooling plate 11, so that the heat generated by the third components 63 is directly conducted to the first liquid cooling plate 11. In other embodiments, another insulating thermal pad 20 may also be disposed between the first liquid cooling plate 11 and the first circuit module 6, so that the heat generated by the third components 63 is conducted to the first liquid cooling plate 11 through the insulating thermal pad 20. The insulating thermal pad 20 may be made of an insulating material having a high thermal conductivity coefficient, such as silicone or ceramic.

Please refer to FIG. 1, in the first embodiment, the power supply device 100 may further include a thermal adhesive 30. The thermal adhesive 30 may be disposed between the first circuit module 6 and the insulating thermal pad 20, and may include a first adhesive 31 corresponding to the first component 61 and a second adhesive 32 corresponding to the second component 62. A thickness of the second adhesive 32 is greater than a thickness of the first adhesive 31, so that the heat generated by the first component 61 is conducted to the second liquid cooling plate 12 through the first adhesive 31 and the insulating thermal pad 20, and the heat generated by the second component 62 is conducted to the second liquid cooling plate 12 through the second adhesive 32 and the insulating thermal pad 20. Specifically, a thickness difference between the second adhesive 32 and the first adhesive 31 is approximately equal to a height difference between the first component 61 and the second component 62, so that the heat generated by the first component 61 and the second component 62 is efficiently conducted to the second liquid cooling plate 12 through the thermal adhesive 30 and the insulating thermal pad 20. In this embodiment, the first adhesive 31 and the second adhesive 32 are independent of each other, but are not limited thereto. The first adhesive 31 and the second adhesive 32 may also be connected to each other. That is, the first adhesive 31 and the second adhesive 32 are respectively a first portion and a second portion of a layer of thermal adhesive 30, the first portion corresponds to the first component 61, and the second portion corresponds to the second component 62.

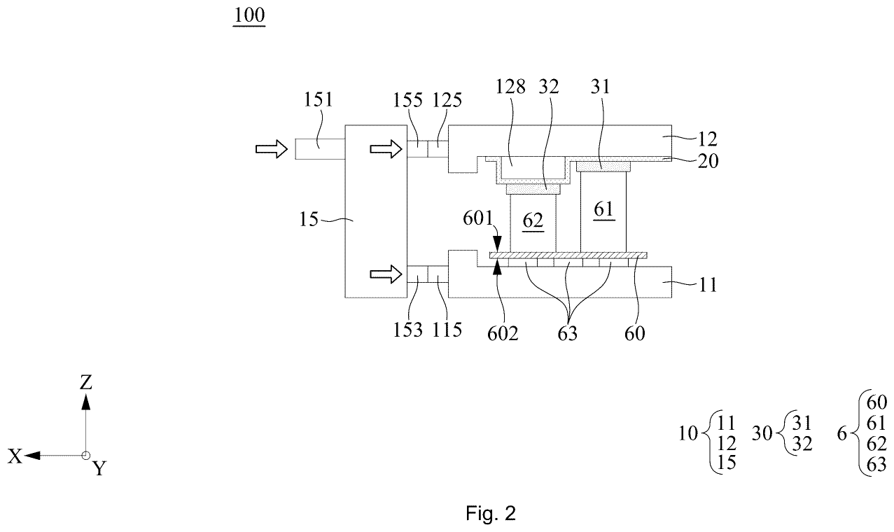

Please refer to FIG. 2, which is a schematic diagram of a power supply device 100 according to a second embodiment of the present disclosure. In the second embodiment, the second liquid cooling plate 12 is provided with a protrusion 128 corresponding to the second component 62, and heat generated by the second component 62 is conducted to the protrusion 128 through the insulating thermal pad 20. Specifically, the protrusion 128 is disposed on a surface of the second liquid cooling plate 12 close to the second component 62. A thickness of the protrusion 128 is approximately equal to the height difference between the first component 61 and the second component 62, and the protrusion 128 may directly or indirectly contact the second component 62 having a smaller heights to remove the heat generated by the second component 62.

Please refer to FIG. 2, in the second embodiment, the power supply device 100 may further include a thermal adhesive 30. The thermal adhesive 30 may be disposed between the first circuit module 6 and the insulating thermal pad 20, and include a first adhesive 31 corresponding to the first component 61 and a second adhesive 32 corresponding to the second component 62. In this embodiment, the thickness of the protrusion 128 is approximately equal to the height difference between the first component 61 and the second component 62, and the thickness of the first adhesive 31 is the same as the thickness of the second adhesive 32, but is not limited thereto. In other embodiments, the thickness of the first adhesive 31 and the thickness of the second adhesive 32 may be different, as long as the thickness of the protrusion 128 plus the thickness of the second adhesive 32 minus the thickness of the first adhesive 31 is approximately equal to the height of the first component 61 minus the height of the second component 62. For example, when the thickness of the protrusion 128 is less than the height difference between the first component 61 and the second component 62, the thickness of the second adhesive 32 is designed to be greater than the thickness of the first adhesive 31. When the thickness of the protrusion 128 is greater than the height difference between the first component 61 and the second component 62, the thickness of the second adhesive 32 is designed to be less than the thickness of the first adhesive 31.

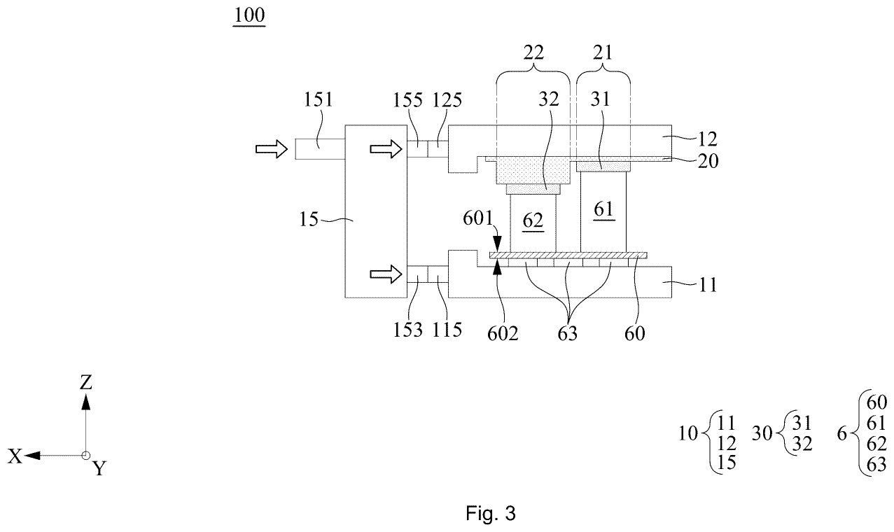

Please refer to FIG. 3, which is a schematic diagram of a power supply device 100 according to a third embodiment of the present disclosure. In the third embodiment, the insulating thermal pad 20 includes a first region 21 corresponding to the first component 61 and a second region 22 corresponding to the second component 62. A thickness of the second region 22 is greater than a thickness of the first region 21, so that heat generated by the first component 61 is conducted to the second liquid cooling plate 12 through the first region 21, and heat generated by the second component 62 is conducted to the second liquid cooling plate 12 through the second region 22. Specifically, a thickness difference between the second region 22 and the first region 21 is approximately equal to the height difference between the first component 61 and the second component 62, so that the heat generated by the first component 61 and the second component 62 is efficiently conducted to the second liquid cooling plate 12 through the insulating thermal pad 20. In this embodiment, the first region 21 and the second region 22 are connected to each other, but are not limited thereto. The first region 21 and the second region 22 may also be independent of each other.

Please refer to FIG. 3, in the third embodiment, the power supply device 100 may further include a thermal adhesive 30. The thermal adhesive 30 may be disposed between the first circuit module 6 and the insulating thermal pad 20, and includes a first adhesive 31 corresponding to the first component 61 and a second adhesive 32 corresponding to the second component 62. In this embodiment, the thickness difference between the first region 21 and the second region 22 is approximately equal to the height difference between the first component 61 and the second component 62, and the thickness of the first adhesive 31 is the same as the thickness of the second adhesive 32, but is not limited thereto. In other embodiments, the thickness of the first adhesive 31 and the thickness of the second adhesive 32 may be different, as long as the thickness of the second region 22 plus the thickness of the second adhesive 32 minus the thickness of the first region 21 minus the thickness of the first adhesive 31 is approximately equal to the height of the first component 61 minus the height of the second component 62.

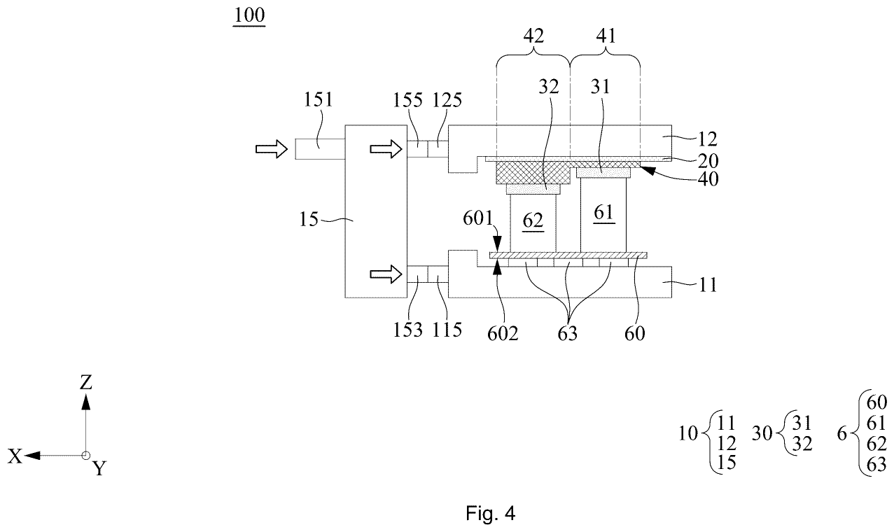

Please refer to FIG. 4, which is a schematic diagram of a power supply device 100 according to a fourth embodiment of the present disclosure. In the fourth embodiment, the power supply device 100 may further include a metal heat sink 40. The metal heat sink 40 is disposed between the first circuit module 6 and the insulating thermal pad 20, and includes a first portion 41 corresponding to the first component 61 and a second portion 42 corresponding to the second component 62. A thickness of the second portion 42 is greater than a thickness of the first portion 41, so that heat generated by the first component 61 is conducted to the second liquid cooling plate 12 through the first portion 41 and the insulating thermal pad 20, and heat generated by the second component 62 is conducted to the second liquid cooling plate 12 through the second portion 42 and the insulating thermal pad 20. Specifically, a thickness difference between the second portion 42 and the first portion 41 is approximately equal to a height difference between the first component 61 and the second component 62, so that the heat generated by the first component 61 and the second component 62 is efficiently conducted to the second liquid cooling plate 12 through the metal heat sink 40 and the insulating thermal pad 20. In this embodiment, the first portion 41 and the second portion 42 are connected to each other, but are not limited thereto. The first portion 41 and the second portion 42 may also be independent of each other. The metal heat sink 40 may be an aluminum extruded heat sink, but is not limited thereto. In some embodiments, the metal heat sink 40 may further extend to cover one or more side surfaces of the first component 61 and/or the second component 62, so that the heat generated by the first component 61 and the second component 62 is more efficiently conducted to the insulating thermal pad 20 and the second liquid cooling plate 12 through the metal heat sink 40.

Please refer to FIG. 4, in the fourth embodiment, the power supply device 100 may further include a thermal adhesive 30. The thermal adhesive 30 may be disposed between the first circuit module 6 and the insulating thermal pad 20, and includes a first adhesive 31 corresponding to the first component 61 and a second adhesive 32 corresponding to the second component 62. In this embodiment, the thickness difference between the second portion 42 and the first region 41 is approximately equal to the height difference between the first component 61 and the second component 62, and the thickness of the first adhesive 31 is the same as the thickness of the second adhesive 32, but is not limited thereto. In other embodiments, the thickness of the first adhesive 31 and the thickness of the second adhesive 32 may be different, as long as the thickness of the second portion 42 plus the thickness of the second adhesive 32 minus the thickness of the first portion 41 minus the thickness of the first adhesive 31 is approximately equal to the height of the first element 61 minus the height of the second element 62.

Please refer to FIG. 1 to FIG. 4, in the first circuit module 6 of the power supply device 100, the first component 61 and the second component 62 having different heights are disposed on an upper surface of the first circuit board 60, and the third components 63 having substantially the same height are disposed on a lower surface of the first circuit board 60. Furthermore, the height difference between the first component 61 and the second component 62 of the first circuit module 6 is compensated by the protrusion 128 of the second liquid cooling plate 12, the thickness difference between the second adhesive 32 and the first adhesive 31 of the thermal adhesive 30, the thickness difference between the second region 22 and the first region 21 of the insulating thermal pad 20, or the thickness difference between the second portion 42 and the first portion 41 of the metal heat sink 40, so that the heat generated by the first component 61 and the second component 62 is efficiently conducted to the second liquid cooling plate 12. The third components 63 having the same height may directly or indirectly contact the first liquid cooling plate 11, so that the heat generated by the third components 63 is directly or indirectly conducted to the first liquid cooling plate 11. In this way, heat dissipation efficiency of the power supply device 100 is significantly improved.

Please refer to FIG. 1 to FIG. 4, a space between the first liquid cooling plate 11 and the second liquid cooling plate 12 is an accommodation space of the liquid cooling rack 10. In FIG. 1 to FIG. 4, the liquid cooling rack 10 accommodates one first circuit module 6, and the first circuit module 6 includes one first component 61 and one second component 62, but is not limited thereto. The liquid cooling rack 10 may accommodate one or more first circuit modules 6, and/or each of the first circuit modules 6 may include one or more first components 61 and one or more second components 62. Correspondingly, in the first embodiment shown in FIG. 1, the thermal adhesive 30 may include one or more first adhesives 31 corresponding to the one or more first components 61, and one or more second adhesives 32 corresponding to the one or more second components 62. In the second embodiment shown in FIG. 2, the second liquid cooling plate 12 is provided with one or more protrusions 128 corresponding to the one or more second components 62. In the third embodiment shown in FIG. 3, the insulating thermal pad 20 includes one or more first regions 21 corresponding to the one or more first components 61, and one or more second regions 22 corresponding to the one or more second components 62. In the fourth embodiment shown in FIG. 4, the metal heat sink 40 includes one or more first portions 41 corresponding to the one or more first components 61, and one or more second portions 42 corresponding to the one or more second components 62. Furthermore, taking a power supply device that provides direct current as an example, the first circuit modules 6 may be DC/DC converters or AC/DC converters. The first components 61 and the second components 62 may include components with irregular shapes such as through-hole components and surface mount devices (SMDs). The through-hole components may include transformers, resistors, capacitors, and inductors. The third components 63 may include components with regular shapes such as metal-oxide-semiconductor field-effect transistors (MOSFET) and diodes. In addition, any two or more of the technical features in the aforementioned embodiments may be combined according to actual needs. For example, the height difference between the first component 61 and the second component 62 of the first circuit module 6 may be compensated by two or more of “the protrusion 128 of the second liquid cooling plate 12, the thickness difference between the second adhesive 32 and the first adhesive 31 of the thermal adhesive 30, the thickness difference between the second region 22 and the first region 21 of the insulating thermal pad 20, and the thickness difference between the second portion 42 and the first portion 41 of the metal heat sink 40”. Alternatively, the power supply device 100 may include two or more of the circuit modules 6 of the first to fourth embodiments.

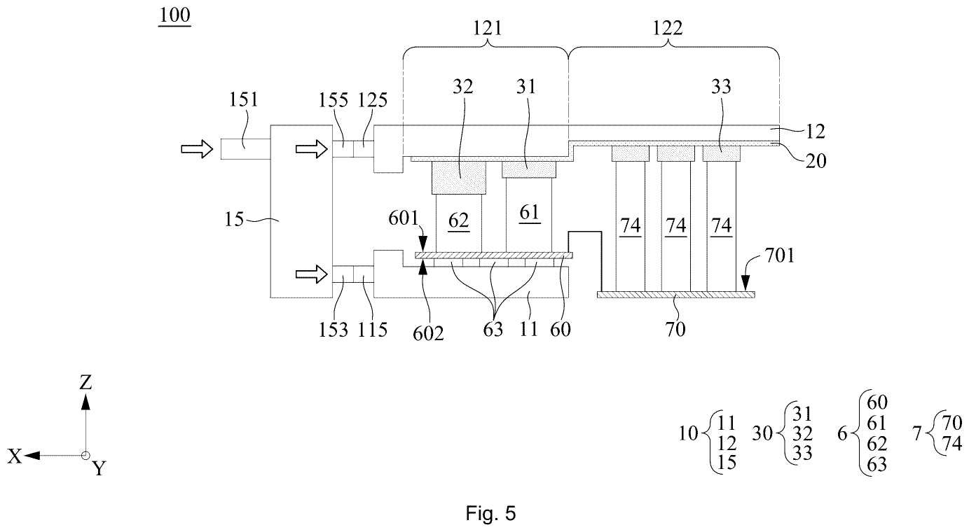

Please refer to FIG. 5, which is a schematic diagram of a power supply device 100 according to a fifth embodiment of the present disclosure. In the fifth embodiment, the power supply device 100 may further include a second circuit module 7. The second circuit module 7 includes a second circuit board 70 and a plurality of fourth components 74. The second circuit board 70 is adjacent to a side of the first liquid cooling plate 11 and is located below the second liquid cooling plate 12. The fourth components 74 are disposed on a surface 701 of the second circuit board 70 close to the second liquid cooling plate 12, and heights of the fourth components 74 are substantially the same and greater than the height of the first component 61. The second liquid cooling plate 12 includes a first plate 121 corresponding to the first circuit module 6 and a second plate 122 corresponding to the second circuit module 7. A thickness of the first plate 121 is greater than a thickness of the second plate 122, so that heat generated by the first component 61 is conducted to the first plate 121 through the insulating thermal pad 20, and heat generated by the fourth components 74 is conducted to the second plate 122 through the insulating thermal pad 20.

In this embodiment, because a bottom surface of the second circuit board 70 of the second circuit module 7 is not provided with electronic components, the second circuit module 7 does not need to be disposed on the first liquid cooling plate 11. Accordingly, a length of the first liquid cooling plate 11 is set to be consistent with a length of the first circuit module 6, so that the length of the first liquid cooling plate 11 is less than a length of the second liquid cooling plate 12, thereby reducing a manufacturing cost of the first liquid cooling plate 11. Furthermore, because the heights of the fourth components 74 are greater than the height of the first component 61, the thickness of the second plate 122 of the second liquid cooling plate 12 corresponding to the second circuit module 7 is designed to be less than the thickness of the first plate 121 of the second liquid cooling plate 12 corresponding to the first circuit module 6. In this way, the bottom surface of the second circuit board 70 of the second circuit module 7 can be flush with a bottom surface of the first liquid cooling plate 11. The second circuit module 7 may be a capacitor module, and the fourth components 74 may be capacitors, but are not limited thereto.

Please refer to FIG. 5, in the fifth embodiment, the power supply device 100 may further include a thermal adhesive 30. The thermal adhesive 30 may be disposed on a bottom surface of the insulating thermal pad 20, and includes a first adhesive 31 corresponding to the first component 61, a second adhesive 32 corresponding to the second component 62, and a plurality of third adhesives 33 corresponding to the fourth components 74. In this embodiment, a thickness of the third adhesives 33 is equal to the thickness of the first adhesive 31 and less than the thickness of the second adhesive 32, but are not limited thereto. The thickness of the third adhesives 33 may be adjusted according to the actual heights of the fourth components 74 and an actual thickness difference between the first plate 121 and the second plate 122 of the second liquid cooling plate 12, so that the bottom surface of the second circuit board 70 of the second circuit module 7 is flush with the bottom surface of the first liquid cooling plate 11.

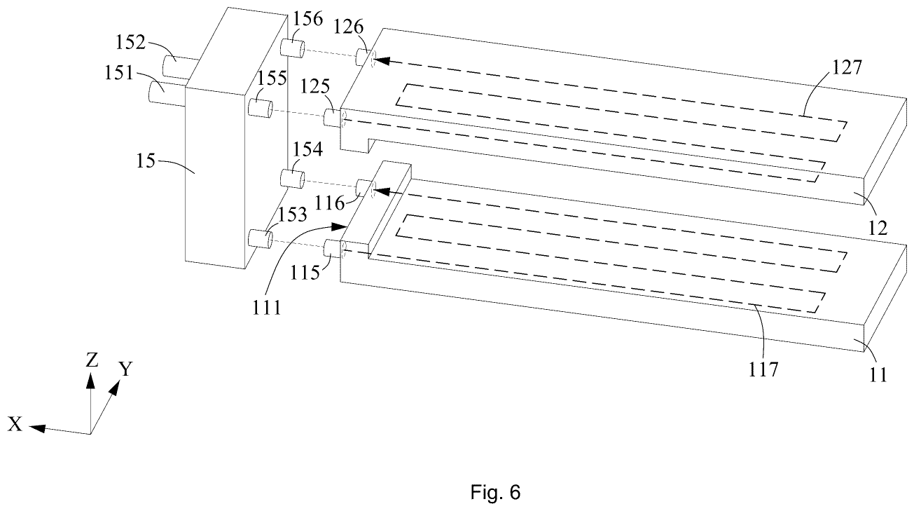

Please refer to FIG. 6, which is an exploded view of a liquid cooling rack 10 according to an embodiment of the present disclosure. The liquid cooling rack 10 may include a first liquid cooling plate 11, a second liquid cooling plate 12, and a manifold 15. The first liquid cooling plate 11 has a first inlet 115, a first outlet 116, and a first flow channel 117. The first inlet 115 and the first outlet 116 are located on a first side 111 of the first liquid cooling plate 11. The first flow channel 117 is located in the first liquid cooling plate 11 and is connected to the first inlet 115 and the first outlet 116. The second liquid cooling plate 12 has a second inlet 125, a second outlet 126, and a second flow channel 127. The second inlet 125 and the second outlet 126 are located on a side of the second liquid cooling plate 12 corresponding to the first side 111 of the first liquid cooling plate 11. The second flow channel 127 is located in the second liquid cooling plate 12 and is connected to the second inlet 125 and the second outlet 126. The manifold 15 is adjacent to the first side 111 of the first liquid cooling plate 11 and is detachably connected to the first inlet 115, the first outlet 116, the second inlet 125, and the second outlet 126. Specifically, the manifold 15 has connection ports 153, 154, 155, and 156 for respectively coupling to the first inlet 115 and the first outlet 116 of the first liquid cooling plate 11 and the second inlet 125 and the second outlet 126 of the second liquid cooling plate 12. The manifold 15 further has an inlet port 151 and an outlet port 152. The inlet port 151 is connected to the first inlet 115 and the second inlet 125. The outlet port 152 is connected to the first outlet 116 and the second outlet 126. The inlet port 151 is configured to receive a cooling liquid from a liquid cooling distribution unit, and the outlet port 152 is configured to transport the cooling liquid that has absorbed heat back to the liquid cooling distribution unit.

In some embodiments, the first liquid cooling plate 11 may include a cover plate and a bottom plate. The bottom plate is provided with a groove. After the cover plate and the bottom plate are assembled, the groove forms the first flow channel 117 for the cooling liquid to flow through. The first flow channel 117 has the first inlet 115 for the cooling liquid to flow into the first flow channel 117, and the first outlet 116 for the cooling liquid to flow out of the first flow channel 117. In an embodiment, the cover plate may be a vapor chamber to improve heat dissipation efficiency. The second liquid cooling plate 12 may have the same structure as the first liquid cooling plate 11.

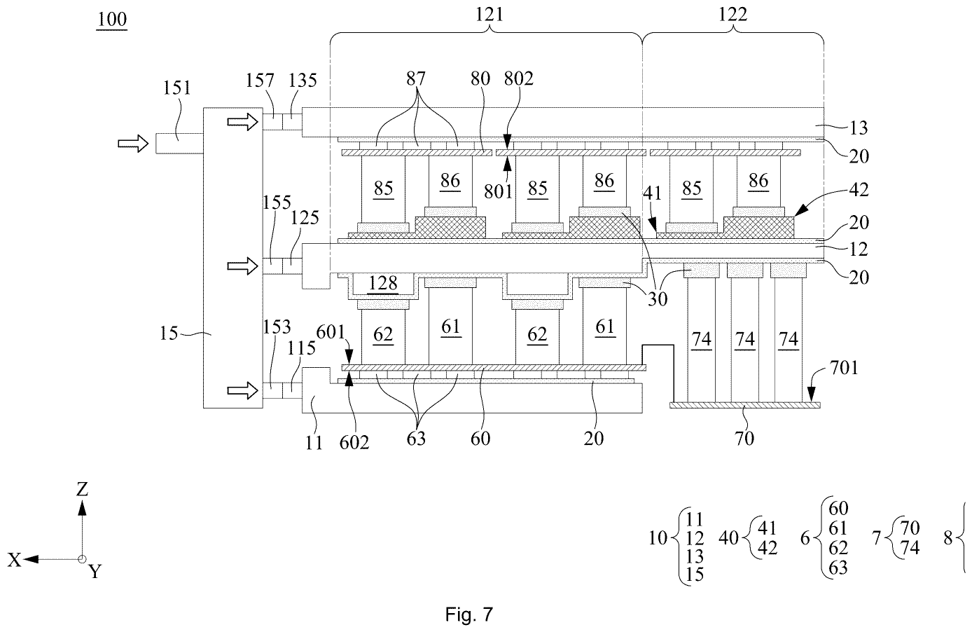

Please refer to FIG. 7, which is a schematic diagram of a power supply device 100 according to a sixth embodiment of the present disclosure. In the sixth embodiment, the power supply device 100 includes a liquid cooling rack 10, a first circuit module 6, a second circuit module 7, a third circuit module 8, and a metal heat sink 40. The liquid cooling rack 10 includes a first liquid cooling plate 11, a second liquid cooling plate 12, and a third liquid cooling plate 13 sequentially from bottom to top. The first circuit module 6 includes a first circuit board 60, at least one first component 61, at least one second component 62, and a plurality of third components 63. The first circuit board 60 is disposed on the first liquid cooling plate 11. The first component 61 and the second component 62 are disposed on a surface of the first circuit board 60 close to the second liquid cooling plate 12, and a height of the first component 61 is greater than a height of the second component 62. The second liquid cooling plate 12 is provided with a protrusion 128. The protrusion 128 directly or indirectly contacts the second component 62. Heights of the third components 63 are substantially the same, and the third components 63 are disposed on a surface of the first circuit board 60 close to the first liquid cooling plate 11 and directly or indirectly contact the first liquid cooling plate 11.

The second circuit module 7 includes a second circuit board 70 and a plurality of fourth components 74. The second circuit board 70 is adjacent to a side of the first liquid cooling plate 11 and is located below the second liquid cooling plate 12. The fourth components 74 are disposed on a surface of the second circuit board 70 close to the second liquid cooling plate 12, and heights of the fourth components 74 are substantially the same and greater than the height of the first component 61. The second liquid cooling plate 12 includes a first plate 121 corresponding to the first circuit module 6 and a second plate 122 corresponding to the second circuit module 7. A thickness of the second plate 122 is less than a thickness of the first plate 121, so that the first component 61 directly or indirectly contacts the first plate 121, and the fourth components 74 directly or indirectly contact the second plate 122. The protrusion 128 is disposed on a bottom surface of the first plate 121, so that the second component 62 indirectly contacts the second plate 122 through the protrusion 128.

The third circuit module 8 includes a third circuit board 80, a fifth component 85, a sixth component 86, and a plurality of seventh components 87. The third circuit board 80 is disposed between the second liquid cooling plate 12 and the third liquid cooling plate 13. The fifth component 85 and the sixth component 86 are disposed on a surface 801 of the third circuit board 80 close to the second liquid cooling plate 12, and a height of the fifth component 85 is greater than a height of the sixth component 86. Heights of the seventh components 87 are substantially the same, and the seventh components 87 are disposed on a surface 802 of the third circuit board 80 close to the third liquid cooling plate 13 and directly or indirectly contact the third liquid cooling plate 13.

The metal heat sink 40 is disposed between the third circuit module 8 and the second liquid cooling plate 12, and includes a first portion 41 corresponding to the fifth component 85 and a second portion 42 corresponding to the sixth component 86. A thickness of the second portion 42 is greater than a thickness of the first portion 41, so that heat generated by the fifth component 85 is conducted to the second liquid cooling plate 12 through the first portion 41, and heat generated by the sixth component 86 is conducted to the second liquid cooling plate 12 through the second portion 42.

The power supply device 100 of the sixth embodiment includes the technical features of the aforementioned embodiments. For details of the first liquid cooling plate 11, the second liquid cooling plate 12, the first circuit module 6, the second circuit module 7, and the metal heat sink 40, please refer to the description of the aforementioned embodiments. A structure of the third liquid cooling plate 13 is similar to a structure of the first liquid cooling plate 11, and a structure of the third circuit module 8 is similar to a structure of the first circuit module 6, so they will not be described in detail herein. In this embodiment, the first circuit module 6 may be an AC/DC converter, the second circuit module 7 may be a capacitor module, and the third circuit module 8 may be a DC/DC converter, but is not limited thereto.

In the sixth embodiment, the power supply device 100 may further include an insulating thermal pad 20. The insulating thermal pad 20 may be disposed between the metal heat sink 40 and the second liquid cooling plate 12, and/or between the third circuit module 8 and the third liquid cooling plate 13, and/or between the first circuit module 6 and the first liquid cooling plate 11, and/or between the first circuit module 6 and the second liquid cooling plate 12. For details of the insulating thermal pad 20, please refer to the description of the aforementioned embodiments.

In the sixth embodiment, the power supply device 100 may further include a thermal adhesive 30. The thermal adhesive 30 may be disposed between the third circuit module 8 and the metal heat sink 40. For details of the thermal adhesive 30, please refer to the description of the aforementioned embodiments.

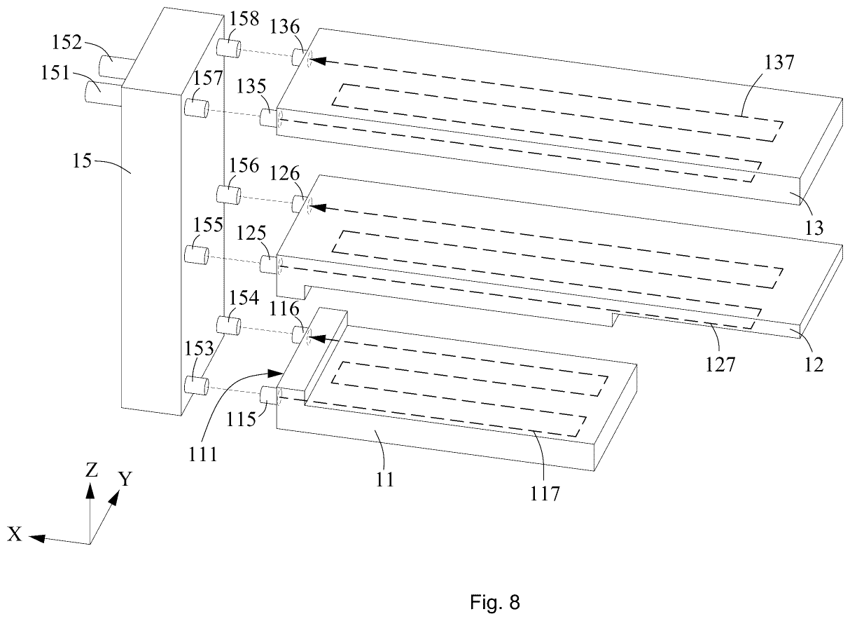

Please refer to FIG. 8, which is an exploded view of the liquid cooling rack 10 in FIG. 7. In the sixth embodiment, the liquid cooling rack 10 may further include a manifold 15. The first liquid cooling plate 11 has a first inlet 115, a first outlet 116, and a first flow channel 117. The first inlet 115 and the first outlet 116 are located on a first side 111 of the first liquid cooling plate 11. The first flow channel 117 is located in the first liquid cooling plate 11 and is connected to the first inlet 115 and the first outlet 116. The second liquid cooling plate 12 has a second inlet 125, a second outlet 126, and a second flow channel 127. The second inlet 125 and the second outlet 126 are located on a side of the second liquid cooling plate 12 corresponding to the first side 111 of the first liquid cooling plate 11. The second flow channel 127 is located in the second liquid cooling plate 12 and is connected to the second inlet 125 and the second outlet 126. The third liquid cooling plate 13 has a third inlet 135, a third outlet 136, and a third flow channel 137. The third inlet 135 and the third outlet 136 are located on a side of the third liquid cooling plate 13 corresponding to the first side 111 of the first liquid cooling plate 11. The third flow channel 137 is located in the third liquid cooling plate 13 and is connected to the third inlet 135 and the third outlet 136. The manifold 15 is adjacent to the first side 111 of the first liquid cooling plate 11 and is detachably connected to the first inlet 115, the first outlet 116, the second inlet 125, the second outlet 126, the third inlet 135, and the third outlet 136. Specifically, the manifold 15 has connection ports 153, 154, 155, 156, 157, and 158 for respectively coupling to the first inlet 115 and the first outlet 116 of the first liquid cooling plate 11, the second inlet 125 and the second outlet 126 of the second liquid cooling plate 12, and the third inlet 135 and the third outlet 136 of the third liquid cooling plate 13. The manifold 15 further has an inlet port 151 and an outlet port 152. The inlet port 151 is connected to the first inlet 115, the second inlet 125, and the third inlet 135. The outlet port 152 is connected to the first outlet 116, the second outlet 126, and the third outlet 136. The inlet port 151 is configured to receive a cooling liquid from a liquid cooling distribution unit, and the outlet port 152 is configured to transport the cooling liquid that has absorbed heat back to the liquid cooling distribution unit.

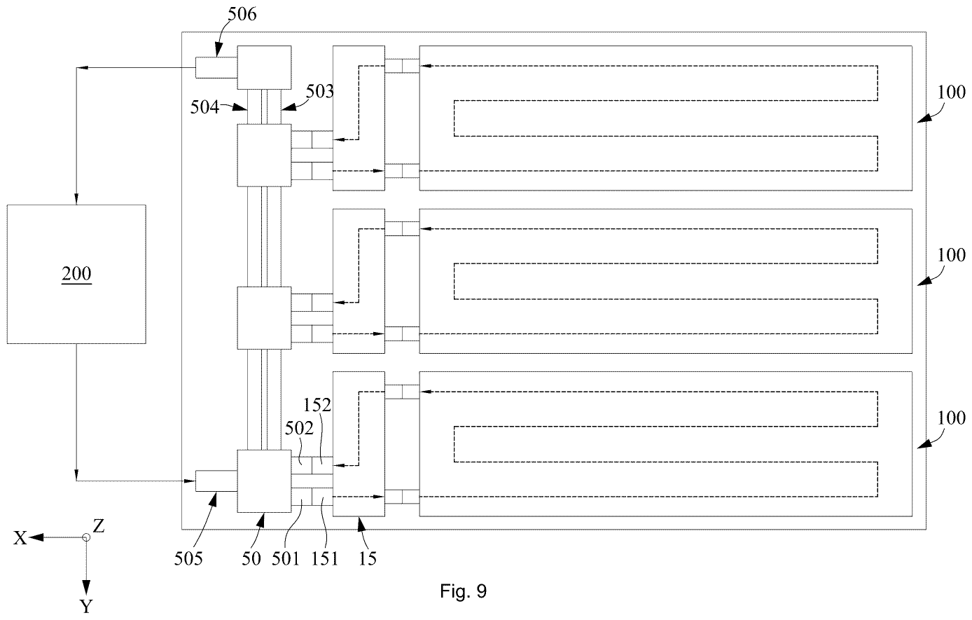

Please refer to FIG. 9, which is a schematic diagram of a power supply system and a liquid cooling distribution unit according to an embodiment of the present disclosure. The power supply system may include a plurality of the power supply devices 100 of any of the above embodiments and a manifold seat 50. The power supply devices 100 are arranged side-by-side in a direction parallel to the first side 111 of the first liquid cooling plate 11 (i.e., a Y direction in FIG. 9). The manifold seat 50 is detachably connected to the inlet port 151 and the outlet port 152 of the manifold 15 of each of the power supply devices 100. Specifically, the manifold seat 50 has a plurality of inflow connectors 501, a plurality of outflow connectors 502, an inflow pipeline 503, and an outflow pipeline 504. The inflow pipeline 503 is connected to the inflow connectors 501, and the inflow connectors 501 are detachably connected to the inlet ports 151 of the manifolds 15. The outflow pipeline 504 is connected to the outflow connectors 502, and the outflow connectors 502 are detachably connected to the outlet ports 152 of the manifolds 15. The manifold seat 50 further includes at least one input port 505 and at least one output port 506. The input port 505 is connected to the inlet port 151 of each of the power supply devices 100 through the inflow pipeline 503 and the inflow connector 501. The output port 506 is connected to the outlet port 152 of each of the power supply devices 100 through the outflow pipeline 504 and the outflow connector 502. The input port 505 and the output port 506 may be connected to a liquid cooling distribution unit 200. The input port 505 is configured to receive a cooling liquid from the liquid cooling distribution unit 200, and the output port 506 is configured to transport the cooling liquid that has absorbed heat back to the liquid cooling distribution unit 200. In an embodiment, the power supply devices 100 may be inserted into a cabinet. When the power supply devices 100 are inserted into a cabinet, the input ports 505 and the output ports 506 of the power supply devices 100 are first connected to liquid cooling pipelines of the cabinet and then connected to the liquid cooling distribution unit 200, so as to ensure flow efficiency of the cooling liquid in liquid cooling plates, thereby improving heat dissipation efficiency. The input port 505 and the output port 506 may be respectively connected to fluid connectors with different flow rates. The fluid connector may include an adjustable flow rate unit for adjusting a flow rate of the cooling liquid flowing through the liquid cooling plate according to heat distribution of each circuit module, so as to optimize distribution of cooling liquid in high-heat and low-heat areas, thereby improving the heat dissipation efficiency and increasing utilization efficiency of cooling liquid.

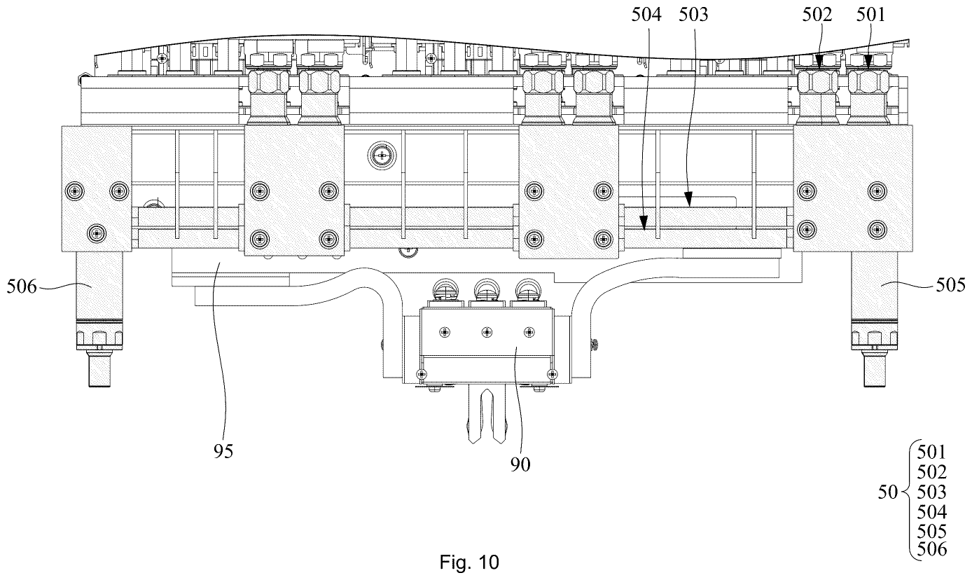

Please refer to FIG. 10, which is a partial enlarged schematic diagram of a power supply system according to an embodiment of the present disclosure. In an embodiment, the power supply system further includes an electrical bus 90 and an insulating thermal sheet 95. The electrical bus 90 is located on a side of the manifold seat 50 away from the power supply devices 100, and is electrically connected to the power supply devices 100. The electrical bus 90 is configured to transmit power generated by the power supply devices 100 to a cabinet, and ensure stability and efficiency of power transmission. Specifically, the electrical bus 90 may include a plurality of electrical connectors. When the power supply devices 100 are inserted into the cabinet, the electrical connectors of the electrical bus 90 are coupled to electrical connectors of the cabinet, thereby electrically connecting the power supply devices 100 and the cabinet. The insulating thermal sheet 95 is disposed between the electrical bus 90 and the manifold seat 50. Heat generated by the electrical bus 90 is conducted to the manifold seat 50 through the insulating thermal sheet 95, thereby preventing the electrical bus 90 from overheating.

The embodiments are described in detail above, so that those skilled in the art can fully understand the concept of the present invention. Based on the foregoing embodiments, all other embodiments obtained by those skilled in the art without creative labor are within the scope of the present invention. Specifically, those skilled in the art may modify the technical solutions in the foregoing embodiments, or replace one or more technical features in the foregoing embodiments with equivalents, so as to achieve the same purposes and/or advantages as the foregoing embodiments. These modifications or equivalent replacements shall fall within the scope of the present invention. Therefore, the scope of the present invention is determined by the appended claims.

What is claimed is:

1. A power supply device, comprising:
a liquid cooling rack comprising a first liquid cooling plate and a second liquid cooling plate located above the first liquid cooling plate;
a first circuit module comprising a first circuit board, a first component, a second component, and a plurality of third components, wherein the first circuit board is disposed on the first liquid cooling plate, the first component and the second component are disposed on a surface of the first circuit board close to the second liquid cooling plate, a height of the first component is greater than a height of the second component, heights of the third components are substantially the same, the third components are disposed on a surface of the first circuit board close to the first liquid cooling plate, and heat generated by the third components is directly or indirectly conducted to the first liquid cooling plate; and
an insulating thermal pad disposed between the first circuit module and the second liquid cooling plate, wherein heat generated by the first component and the second component is conducted to the second liquid cooling plate through the insulating thermal pad.

2. The power supply device according to claim 1, wherein the second liquid cooling plate is provided with a protrusion corresponding to the second component, and heat generated by the second component is conducted to the protrusion through the insulating thermal pad.

3. The power supply device according to claim 1, wherein the insulating thermal pad comprises a first region corresponding to the first component and a second region corresponding to the second component, and a thickness of the second region is greater than a thickness of the first region, so that heat generated by the first component is conducted to the second liquid cooling plate through the first region, and heat generated by the second component is conducted to the second liquid cooling plate through the second region.

4. The power supply device according to claim 1, further comprising:
a thermal adhesive disposed between the first circuit module and the insulating thermal pad, and comprising a first adhesive corresponding to the first component and a second adhesive corresponding to the second component, wherein a thickness of the second adhesive is greater than a thickness of the first adhesive, so that heat generated by the first component is conducted to the second liquid cooling plate through the first adhesive and the insulating thermal pad, and heat generated by the second component is conducted to the second liquid cooling plate through the second adhesive and the insulating thermal pad.

5. The power supply device according to claim 1, further comprising:
a metal heat sink disposed between the first circuit module and the insulating thermal pad, and comprising a first portion corresponding to the first component and a second portion corresponding to the second component, wherein a thickness of the second portion is greater than a thickness of the first portion, so that heat generated by the first component is conducted to the second liquid cooling plate through the first portion and the insulating thermal pad, and heat generated by the second component is conducted to the second liquid cooling plate through the second portion and the insulating thermal pad.

6. The power supply device according to claim 1, further comprising:
a second circuit module comprising a second circuit board and a plurality of fourth components, wherein the second circuit board is adjacent to a side of the first liquid cooling plate and is located below the second liquid cooling plate, the fourth components are disposed on a surface of the second circuit board close to the second liquid cooling plate, and heights of the fourth components are substantially the same and are greater than the height of the first component;
wherein the second liquid cooling plate comprises a first plate corresponding to the first circuit module and a second plate corresponding to the second circuit module, and a thickness of the first plate is greater than a thickness of the second plate, so that heat generated by the first component is conducted to the first plate through the insulating thermal pad, and heat generated by the fourth components is conducted to the second plate through the insulating thermal pad.

7. The power supply device according to claim 1, wherein
the first liquid cooling plate has a first inlet, a first outlet, and a first flow channel, the first inlet and the first outlet are located on a first side of the first liquid cooling plate, and the first flow channel is located in the first liquid cooling plate and is connected to the first inlet and the first outlet;
the second liquid cooling plate has a second inlet, a second outlet and a second flow channel, the second inlet and the second outlet are located on a side of the second liquid cooling plate corresponding to the first side, and the second flow channel is located in the second liquid cooling plate and is connected to the second inlet and the second outlet; and
the liquid cooling rack further comprises a manifold, the manifold is adjacent to the first side and detachably connected to the first inlet, the first outlet, the second inlet and the second outlet, and has an inlet port and an outlet port, the inlet port is connected to the first inlet and the second inlet, and the outlet port is connected to the first outlet and the second outlet.

8. A power supply device, comprising:
a liquid cooling rack comprising a first liquid cooling plate, a second liquid cooling plate, and a third liquid cooling plate sequentially from bottom to top;
a first circuit module comprising a first circuit board, a first component, a second component, and a plurality of third components, wherein the first circuit board is disposed on the first liquid cooling plate, the first component and the second component are disposed on a surface of the first circuit board close to the second liquid cooling plate, a height of the first component is greater than a height of the second component, the second liquid cooling plate is provided with a protrusion, the protrusion directly or indirectly contacts the second component, heights of the third components are substantially the same, and the third components are disposed on a surface of the first circuit board close to the first liquid cooling plate and directly or indirectly contact the first liquid cooling plate;
a second circuit module comprising a second circuit board and a plurality of fourth components, wherein the second circuit board is adjacent to a side of the first liquid cooling plate and is located below the second liquid cooling plate, the fourth components are disposed on a surface of the second circuit board close to the second liquid cooling plate, heights of the fourth components are substantially the same and are greater than the height of the first component, the second liquid cooling plate comprises a first plate corresponding to the first circuit module and a second plate corresponding to the second circuit module, and a thickness of the second plate is less than a thickness of the first plate, so that the first component directly or indirectly contacts the first plate, and the fourth components directly or indirectly contact the second plate;
a third circuit module comprising a third circuit board, a fifth component, a sixth component, and a plurality of seventh components, wherein the third circuit board is disposed between the second liquid cooling plate and the third liquid cooling plate, the fifth component and the sixth component are disposed on a surface of the third circuit board close to the second liquid cooling plate, a height of the fifth component is greater than a height of the sixth component, heights of the seventh components are substantially the same, and the seventh components are disposed on a surface of the third circuit board close to the third liquid cooling plate and directly or indirectly contact the third liquid cooling plate; and
a metal heat sink disposed between the third circuit module and the second liquid cooling plate, and comprising a first portion corresponding to the fifth component and a second portion corresponding to the sixth component, wherein a thickness of the second portion is greater than a thickness of the first portion, so that heat generated by the fifth component is conducted to the second liquid cooling plate through the first portion, and heat generated by the sixth component is conducted to the second liquid cooling plate through the second portion.

9. The power supply device according to claim 8, further comprising:
an insulating thermal pad disposed between the metal heat sink and the second liquid cooling plate, or between the third circuit module and the third liquid cooling plate, or between the first circuit module and the first liquid cooling plate, or between the first circuit module and the second liquid cooling plate.

10. The power supply device according to claim 8, further comprising:
a thermal adhesive disposed between the third circuit module and the metal heat sink.

11. The power supply device according to claim 8, wherein
the first liquid cooling plate has a first inlet, a first outlet, and a first flow channel, the first inlet and the first outlet are located on a first side of the first liquid cooling plate, and the first flow channel is located in the first liquid cooling plate and is connected to the first inlet and the first outlet;
the second liquid cooling plate has a second inlet, a second outlet, and a second flow channel, the second inlet and the second outlet are located on a side of the second liquid cooling plate corresponding to the first side, and the second flow channel is located in the second liquid cooling plate and is connected to the second inlet and the second outlet;
the third liquid cooling plate has a third inlet, a third outlet, and a third flow channel, the third inlet and the third outlet are located on a side of the third liquid cooling plate corresponding to the first side, and the third flow channel is located in the third liquid cooling plate and is connected to the third inlet and the third outlet; and
the liquid cooling rack further comprises a manifold, the manifold is adjacent to the first side, is detachably connected to the first inlet, the first outlet, the second inlet, the second outlet, the third inlet, and the third outlet, and has an inlet port and an outlet port, the inlet port is connected to the first inlet, the second inlet, and the third inlet, and the outlet port is connected to the first outlet, the second outlet, and the third outlet.

12. A power supply system, comprising:
a plurality of the power supply devices according to claim 7, wherein the power supply devices are arranged side-by-side in a direction parallel to the first side of the first liquid cooling plate; and
a manifold seat detachably connected to the inlet port and the outlet port of the manifold of each of the power supply devices, and having an input port and an output port, wherein the input port is connected to the inlet port of each of the power supply devices, and the output port is connected to the outlet port of each of the power supply devices.

13. The power supply system according to claim 12, further comprising:
an electrical bus located on a side of the manifold seat away from the power supply devices, and electrically connected to the power supply devices; and
an insulating thermal sheet disposed between the electrical bus and the manifold seat, wherein heat generated by the electrical bus is conducted to the manifold seat through the insulating thermal sheet.
